(19) United States
(12) Patent Application Publication
(10) Pub. No.: US 2025/0338630 A1
(43) Pub. Date: Oct. 30, 2025

(54) P-I-N DIODE IN ESD PROTECTION CIRCUIT WITH BACKSIDE TERMINAL

(71) Applicant: Taiwan Semiconductor Manufacturing Company, Ltd., Hsinchu (TW)

(72) Inventors: Tao-Yi HUNG, Hsinchu (TW); Wun-Jie LIN, Hsinchu (TW); Jam-Wem LEE, Hsinchu (TW); Kuo-Ji CHEN, Hsinchu (TW)

(21) Appl. No.: 18/650,838

(22) Filed: Apr. 30, 2024

(51) Int. Cl. H01L 27/02; H01L 23/522; H01L 23/528; H02H 9/02

(52) U.S. Cl. CPC H10D 89/611; H01L 23/5226; H01L 23/5286; H02H 9/02

(57) ABSTRACT

A device including a substrate having a frontside and a backside, a first P-I-N diode situated on the frontside of the substrate, a first terminal situated under the backside of the substrate, a plurality of frontside conductive layers, and a plurality of backside conductive layers. The plurality of frontside conductive layers situated over the first P-I-N diode and electrically connected to the first P-I-N diode. The plurality of backside conductive layers situated under the backside of the substrate and electrically connected to the first terminal that is electrically connected to the first P-I-N diode through the plurality of backside conductive layers and at least one via.

### BACKGROUND

Sometimes, electrostatic discharge (ESD) causes failures in electronic devices, such as integrated circuits (ICs). ESD is a sudden and momentary flow of electric current between two differently charged objects that can damage electronic components in the devices. Typically, manufactures build ESD protection circuits to protect the electronic components from the effects of ESD. Often the ESD protection circuits include diodes and clamping circuits to prevent or mitigate damage to the electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a device, in accordance with some embodiments.

FIG. 2 is a diagram schematically illustrating a cross-section of a P-I-N diode, in accordance with some embodiments.

FIG. 3 is a diagram schematically illustrating a top-view of the P-I-N diode, in accordance with some embodiments.

FIG. 4 is a diagram schematically illustrating a device that includes a substrate and feed-through-vias (FTVs), in accordance with some embodiments.

FIG. 5 is a circuit diagram schematically illustrating the device of FIG. 4 with a power-rail clamping circuit, in accordance with some embodiments.

FIG. 6 is a diagram schematically illustrating a device that includes a substrate and bottom vias, also referred to as backside vias (VBs), in accordance with some embodiments.

FIG. 7 is a diagram schematically illustrating a top-view of the first P-I-N diode, in accordance with some embodiments.

FIG. 8 is a circuit diagram schematically illustrating the device of FIG. 6 with a power-rail clamping circuit, in accordance with some embodiments.

FIG. 9 is a diagram schematically illustrating a device that includes a substrate, FTVs, and VBs, in accordance with some embodiments.

FIG. 10 is a circuit diagram schematically illustrating the device of FIG. 9 with a power-rail clamping circuit, in accordance with some embodiments.

FIG. 11 is a circuit diagram schematically illustrating a device that includes IO signal channel impedance matching networks, in accordance with some embodiments.

FIG. 12 is a flow-chart diagram schematically illustrating a method of manufacturing an ESD protection circuit, in accordance with some embodiments.

FIG. 13 is a block diagram schematically illustrating an example of a computer system configured to provide the electronic devices, semiconductor devices, and methods of the current disclosure, in accordance with some embodiments.

FIG. 14 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed embodiments provide ESD protection circuits and schemes that include at least one P-Intrinsic-N (P-I-N) diode that includes a P+ region, an N+ region, and an intrinsic region situated between the P+ region and the N+ region. The P-I-N diodes can be manufactured in a bulk-less process, such as a silicon-on-insulator (SOI) process and/or a super power rail (SPR) process. In some embodiments, the intrinsic region is a lightly doped p-type substrate. In some embodiments, the ESD protection circuits and schemes include one or more ESD power-rail clamping circuits.

Disclosed embodiments provide a device that includes a substrate having a frontside and a backside with a P-I-N diode situated on the frontside of the substrate and a terminal situated under the backside of the substrate. A plurality of frontside conductive layers are situated over the P-I-N diode and electrically connected to the P-I-N diode, and a plurality of backside conductive layers are situated under the backside of the substrate and electrically connected to the terminal. The terminal is electrically connected to the P-I-N diode through the plurality of backside conductive layers and at least one via.

In some embodiments, the at least one via includes a feed-through-via (FTV) that extends through the substrate from the backside of the substrate to the frontside of the substrate, where the plurality of backside conductive layers are electrically connected to the plurality of frontside conductive layers by the FTV. In some embodiments, the at least one via includes a bottom via, also referred to as a backside via (VB) that extends through the substrate from the backside of the substrate to one side of the P-I-N diode, where the plurality of backside conductive layers are electrically connected to the one side of the P-I-N diode by the VB. The plurality of frontside conductive layers are electrically connected to the one side of the P-I-N diode, such that the plurality of backside conductive layers are electrically connected to the plurality of frontside conductive layers through the VB and the one side of the P-I-N diode.

In some embodiments, the devices do not have or include capacitors between power/reference terminals and input/output (IO) terminals, such as between a VDD power terminal and an IO terminal and/or between an IO terminal and a VSS reference terminal. In some embodiments, the lack of capacitors between the power/reference terminals and the IO terminals is due to the larger distances between the power/reference terminals and the IO terminals. Also, in some embodiments, matching networks for matching the impedance of the IO signal channel to the device are included between the power/reference terminals and the IO terminals, where the matching networks include capacitors, inductors, and/or resistors situated in the space between terminals.

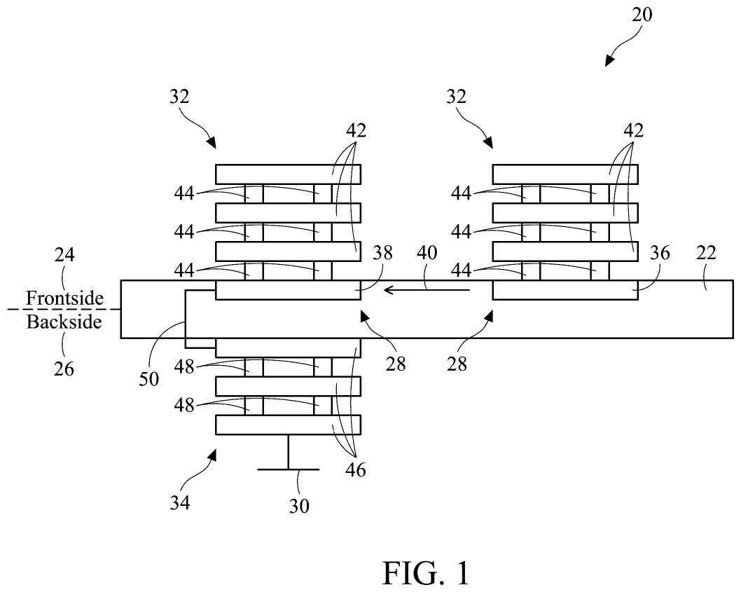

FIG. 1 is a diagram schematically illustrating a device 20, in accordance with some embodiments. The device 20 includes a substrate 22 that has a frontside 24 and a backside 26. In some embodiments, the substrate 22 is a bulk-less process substrate. In some embodiments, the substrate 22 is an SOI substrate. In some embodiments, the substrate 22 is a silicon-insulator-silicon substrate. In some embodiments, the substrate 22 is an SPR process substrate. In some embodiments, the device 20 is a semiconductor device, an IC device, and/or an electronic device. In some embodiments, the device 20 including the substrate 22 is part of a wafer.

The device 20 includes a P-I-N diode 28, a terminal 30, a plurality of frontside conductive layers 32, and a plurality of backside conductive layers 34. The P-I-N diode 28 includes a P+ region 36, an N+ region 38, and an intrinsic region 40. The P-I-N diode 28 is situated on the frontside 24 of the substrate 22. The terminal 30 is situated under the backside 26 of the substrate 22. In some embodiments, the terminal 30 is one of a power terminal, such as a VDD power terminal, a reference terminal, such as a VSS reference terminal and/or a ground terminal, and an IO terminal.

The plurality of frontside conductive layers 32 include conductive layers 42, such as metal layers, and vias 44 in stacks. The plurality of frontside conductive layers 32 are situated over the P-I-N diode and electrically connected to the P-I-N diode. The plurality of backside conductive layers 34 include conductive layers 46, such as metal layers, and vias 48 in stacks. The plurality of backside conductive layers 34 are situated under the backside of the substrate 22 and electrically connected to the terminal 30.

The terminal 30 is electrically connected to the P-I-N diode 28 through the plurality of backside conductive layers 34 and at least one via 50 in the substrate 22. The via 50 is indicated by a connection between the plurality of backside conductive layers 34 and one side of the P-I-N diode 28.

In some embodiments, the at least one via 50 includes an FTV that extends through the substrate 22 from the backside 26 of the substrate 22 to the frontside 24 of the substrate 22, where the plurality of backside conductive layers 34 are electrically connected to the plurality of frontside conductive layers 32 by the FTV. In some embodiments, the at least one via 50 includes a VB that extends through the substrate 22 from the backside 26 of the substrate 22 to one side of the P-I-N diode 28, where the plurality of backside conductive layers 34 are electrically connected to the one side of the P-I-N diode 28 by the VB. The plurality of frontside conductive layers 32 are electrically connected to the one side of the P-I-N diode 28, such that the plurality of backside conductive layers 34 are electrically connected to the plurality of frontside conductive layers 32 through the VB and the one side of the P-I-N diode 28.

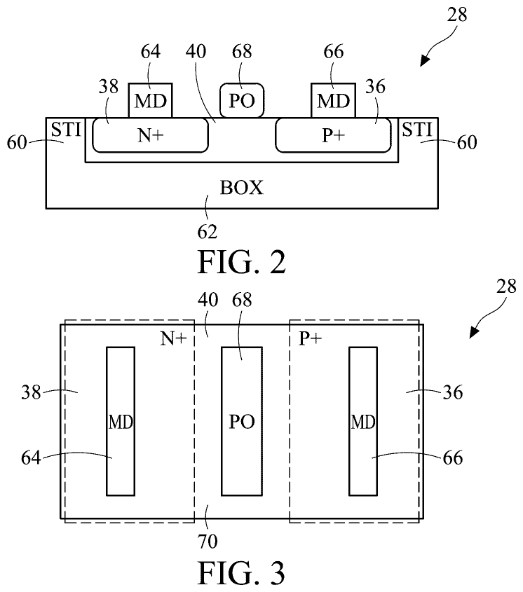

FIG. 2 is a diagram schematically illustrating a cross-section of the P-I-N diode 28, in accordance with some embodiments. The P-I-N diode 28 includes the P+ region 36, the N+ region 38, and the intrinsic region 40 surrounded by a shallow trench isolation (STI) region 60. A buried oxide (BOX) layer 62 is situated underneath the intrinsic region 40. A metal over diffusion (MD) layer 64 is formed on the N+ region 38, and an MD layer 66 is formed on the P+ region 36. A polycrystalline silicon (polysilicon or poly) PO layer 68 is formed on the intrinsic region 40.

FIG. 3 is a diagram schematically illustrating a top-view of the P-I-N diode 28, in accordance with some embodiments. The P-I-N diode 28 includes the P+ region 36, the N+ region 38, and the intrinsic region 40. The MD layer 66 is formed on the P+ region 36 and the MD layer 64 is formed on the N+ region 38. The PO layer 68 is formed on the intrinsic region 40. The P-I-N diode 28 includes an active region 70, also referred to as an oxide diffusion region, that includes the P+ region 36, the N+ region 38, and the intrinsic region 40.

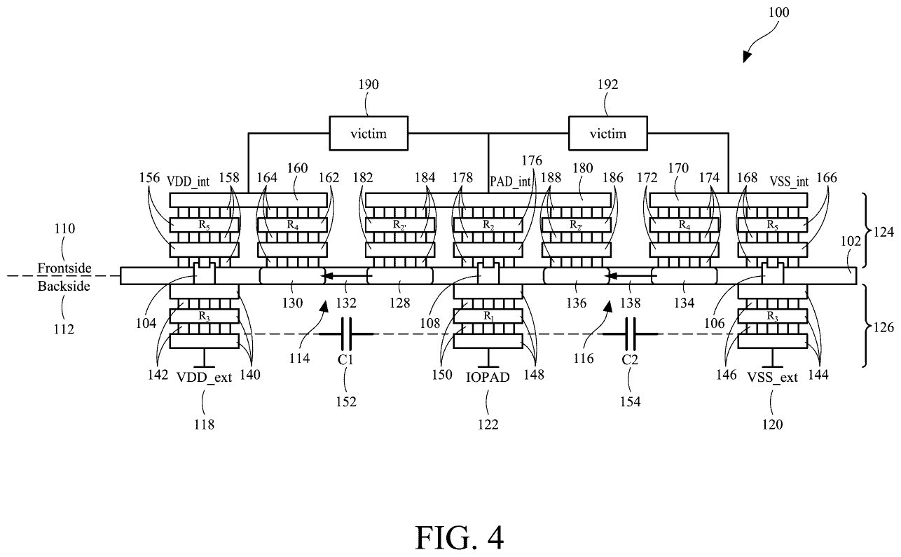

FIG. 4 is a diagram schematically illustrating a device 100 that includes a substrate 102 and FTVs 104, 106, and 108, in accordance with some embodiments. Each of the FTVs 104, 106, and 108 is a conductive path though the substrate 102. In some embodiments, the device 100 is a semiconductor device, an IC device, and/or an electronic device. In some embodiments, the device 100 is part of a wafer. In some embodiments, the device 100 is like the device 20 of FIG. 1.

The device 100 includes the substrate 102 that has a frontside 110 and a backside 112. Each of the FTVs 104, 106, and 108 extends though the substrate 102 from the frontside 110 to the backside 112. In some embodiments, the substrate 102 is a bulk-less process substrate. In some embodiments, the substrate 102 is an SOI substrate. In some embodiments, the substrate 102 is a silicon-insulator-silicon substrate. In some embodiments, the substrate 102 is an SPR process substrate.

The device 100 includes a first P-I-N diode 114, a second P-I-N diode 116, an external VDD power terminal VDD_ext. 118, an external VSS reference terminal VSS_ext. 120, an external IO terminal IOPAD 122, a plurality of frontside conductive layers 124, and a plurality of backside conductive layers 126. The first P-I-N diode 114 and the second P-I-N diode 116 are situated on the frontside 110 of the substrate 102. The first P-I-N diode 114 includes a P+ region 128, an N+ region 130, and an intrinsic region 132. The second P-I-N diode 116 includes a P+ region 134, an N+ region 136, and an intrinsic region 138. Each of the external VDD power terminal VDD_ext. 118, the external VSS reference terminal VSS_ext. 120, and the external IO terminal IOPAD 122 is situated under the backside 112 of the substrate 102.

The external VDD power terminal VDD_ext. 118, the external VSS reference terminal VSS_ext. 120, and the external IO terminal IOPAD 122 are electrically connected to the plurality of backside conductive layers 126. The external VDD power terminal VDD_ext. 118 is electrically connected to backside conductive paths 140 and vias 142 (resistor R3), which are electrically connected to the first FTV 104. The external VSS reference terminal VSS_ext. 120 is electrically connected to backside conductive paths 144 and vias 146 (resistor R3), which are electrically connected to the second FTV 106. The external IO terminal IOPAD 122 is electrically connected to backside conductive paths 148 and vias 150 (resistor R1), which are electrically connected to the third FTV 108.

In some embodiments, a first capacitor C1 152 is situated between the external VDD power terminal VDD_ext. 118 and the external IO terminal IOPAD 122, where one side of the first capacitor C1 152 is at the external VDD power terminal VDD_ext. 118 and another side of the first capacitor C1 152 is at the external IO terminal IOPAD 122. In some embodiments, a second capacitor C2 154 is situated between the external VSS reference terminal VSS_ext. 120 and the external IO terminal IOPAD 122, where one side of the second capacitor C2 154 is at the external VSS reference terminal VSS_ext. 120 and another side of the second capacitor C2 154 is at the external IO terminal IOPAD 122.

Each of the first P-I-N diode 114 and the second P-I-N diode 116 is electrically connected to the plurality of frontside conductive layers 124. The first FTV 104 is electrically connected to the N+ region 130 of the first P-I-N diode 114 through frontside conductive paths 156 and vias 158 (resistor R5), the internal VDD power terminal VDD_int. 160, and the frontside conductive paths 162 and vias 164 (resistor R4) to the N+ region 130 of the first P-I-N diode 114. The second FTV 106 is electrically connected to the P+ region 134 of the second P-I-N diode 116 through frontside conductive paths 166 and vias 168 (resistor R5), the internal VSS reference terminal VSS_int. 170, and the frontside conductive paths 172 and vias 174 (resistor R4) to the P+ region 134 of the second P-I-N diode 116.

The third FTV 108 is electrically connected to the P+ region 128 of the first P-I-N diode 114 and to the N+ region 136 of the second P-I-N diode 116 through frontside conductive paths 176 and vias 178 (resistor R2), the internal IO terminal PAD_int. 180, and to the frontside conductive paths 182 and vias 184 (resistor R2′) to the P+ region 128 of the first P-I-N diode 114 and to the frontside conductive paths 186 and vias 188 (resistor R2′) to the N+ region 136 of the second P-I-N diode 116.

The internal VDD power terminal VDD_int. 160 is electrically connected to internal circuit victims 190 that are electrically connected to the internal IO terminal PAD_int. 180. Also, the internal VSS reference terminal VSS_int. 170 is electrically connected to internal circuit victims 192 that are electrically connected to the internal IO terminal PAD_int. 180.

In operation, the first P-I-N diode 114 protects the internal circuit victims 190 from ESD by shunting ESD current from the external IO terminal IOPAD 122 through the third FTV 108, the first P-I-N diode 114, and the first FTV 104 to the external VDD power terminal VDD_ext. 118, bypassing the internal circuit victims 190. The second P-I-N diode 116 protects the internal circuit victims 192 from ESD by shunting the ESD current from the external VSS reference terminal VSS_ext. 120 through the second FTV 106, the second P-I-N diode 116, and the third FTV 108 to the external IO terminal IOPAD 122, bypassing the internal circuit victims 192.

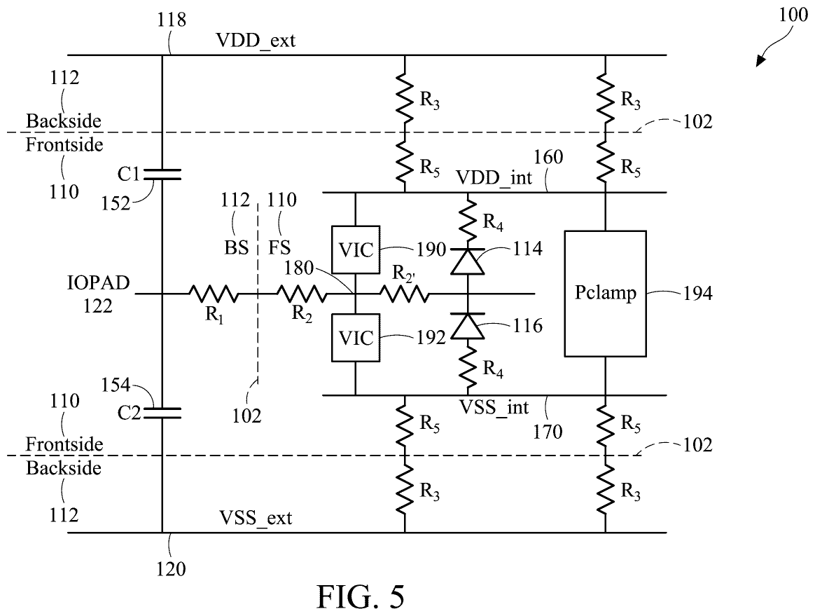

FIG. 5 is a circuit diagram schematically illustrating the device 100 of FIG. 4 with a power-rail clamping circuit 194, in accordance with some embodiments. The device 100 includes the substrate 102 that has the frontside 110 and the backside 112. The device 100 includes the first P-I-N diode 114, the second P-I-N diode 116, the external VDD power terminal VDD_ext. 118, the external VSS reference terminal VSS_ext. 120, and the external IO terminal IOPAD 122. The first P-I-N diode 114 and the second P-I-N diode 116 are situated on the frontside 110 of the substrate 102. Each of the external VDD power terminal VDD_ext. 118, the external VSS reference terminal VSS_ext. 120, and the external IO terminal IOPAD 122 is situated under the backside 112 of the substrate 102.

Under the backside 112, the external VDD power terminal VDD_ext. 118 is electrically connected to resistors R3, the external VSS reference terminal VSS_ext. 120 is electrically connected to resistors R3, and the external IO terminal IOPAD 122 is electrically connected to resistor R1. The first capacitor C1 152 is electrically connected on one side to the external VDD power terminal VDD_ext. 118 and on another side to the external IO terminal IOPAD 122. The second capacitor C2 154 is electrically connected on one side to the external VSS reference terminal VSS_ext. 120 and on another side to the external IO terminal IOPAD 122.

The first P-I-N diode 114 is electrically connected to the resistor R4 that is electrically connected to the internal VDD power terminal VDD_int. 160. The resistors R5 are electrically connected to the internal VDD power terminal VDD_int. 160 and to the resistors R3, such as through the first FTV 104. Also, the second P-I-N diode 116 is electrically connected to the resistor R4 that is electrically connected to the internal VSS reference terminal VSS_int. 170. The resistors R5 are electrically connected to the internal VSS reference terminal VSS_int. 170 and to the resistors R3, such as through the second FTV 106.

Each of the first P-I-N diode 114 and the second P-I-N diode 116 is electrically connected to a resistor R2′ that is electrically connected to the internal IO terminal PAD_int. 180 and resistor R2. The resistor R2 is electrically connected to the resistor R1 and the external IO terminal IOPAD 122 through the third FTV 108.

The internal VDD power terminal VDD_int. 160 is electrically connected to internal circuit victims 190 that are electrically connected to the internal IO terminal PAD_int. 180. Also, the internal VSS reference terminal VSS_int. 170 is electrically connected to internal circuit victims 192 that are electrically connected to the internal IO terminal PAD_int. 180.

The power-rail clamping circuit 194 is electrically connected to the internal VDD power terminal VDD_int. 160 and to the internal VSS reference terminal VSS_int. 170.

The internal VDD power terminal VDD_int. 160 is electrically connected to the external VDD power terminal VDD_ext. 118 through resistors R5 and R3 and, in some embodiments, another FTV. Also, the internal VSS reference terminal VSS_int. 170 is electrically connected to the external VSS reference terminal VSS_ext. 120 through resistors R5 and R3 and, in some embodiments, another FTV.

In operation, the first P-I-N diode 114 protects the internal circuit victims 190 from ESD by shunting ESD current from the external IO terminal IOPAD 122 through the resistors R1, R2, and R2′, the first P-I-N diode 114, and the resistors R4, R5, and R3 to the external VDD power terminal VDD_ext. 118, bypassing the internal circuit victims 190. The second P-I-N diode 116 protects the internal circuit victims 192 from ESD by shunting the ESD current from the external VSS reference terminal VSS_ext. 120 through the resistors, R3, R5, and R4, the second P-I-N diode 116, and the resistors R2′, R2, and RI to the external IO terminal IOPAD 122, bypassing the internal circuit victims 192.

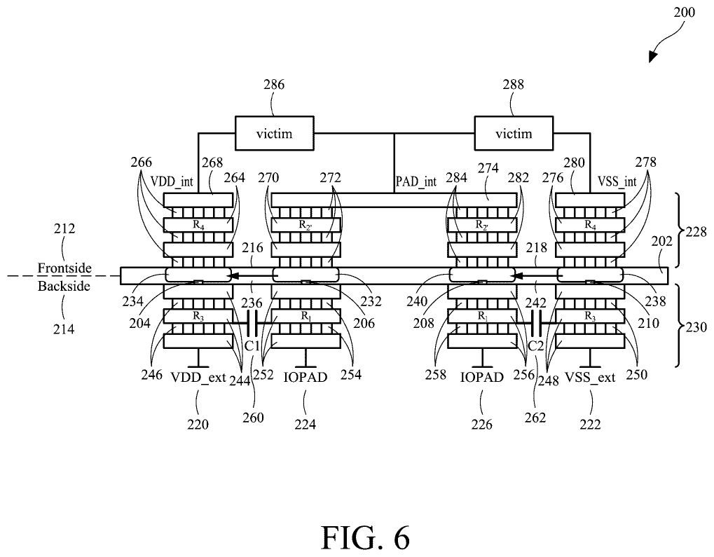

FIG. 6 is a diagram schematically illustrating a device 200 that includes a substrate 202 and VBs 204, 206, 208, and 210, in accordance with some embodiments. Each of the VBs 204, 206, 208, and 210 is a conductive path through at least part of the substrate 202. In some embodiments, the device 200 is a semiconductor device, an IC device, and/or an electronic device. In some embodiments, the device 200 is part of a wafer. In some embodiments, the device 200 is like the device 20 of FIG. 1.

The device 200 includes the substrate 202 that has a frontside 212 and a backside 214, a first P-I-N diode 216, and a second P-I-N diode 218. Each of the VBs 204, 206, 208, and 210 extends though the substrate 202 from the backside 214 to one of the first P-I-N diode 216 and the second P-I-N diode 218. In some embodiments, the substrate 202 is a bulk-less process substrate. In some embodiments, the substrate 202 is an SOI substrate. In some embodiments, the substrate 202 is a silicon-insulator-silicon substrate. In some embodiments, the substrate 202 is an SPR process substrate.

The device 200 includes the first P-I-N diode 216, the second P-I-N diode 218, an external VDD power terminal VDD_ext. 220, an external VSS reference terminal VSS_ext. 222, an external IO terminal IOPAD 224, an external IO terminal IOPAD 226, a plurality of frontside conductive layers 228, and a plurality of backside conductive layers 230. The first P-I-N diode 216 and the second P-I-N diode 218 are situated on the frontside 212 of the substrate 202. The first P-I-N diode 216 includes a P+ region 232, an N+ region 234, and an intrinsic region 236. The second P-I-N diode 218 includes a P+region 238, an N+ region 240, and an intrinsic region 242. Each of the external VDD power terminal VDD_ext. 220, the external VSS reference terminal VSS_ext. 222, and the external IO terminals IOPAD 224 and 226 is situated under the backside 214 of the substrate 202.

The external VDD power terminal VDD_ext. 220, the external VSS reference terminal VSS_ext. 222, and the external IO terminals IOPAD 224 and 226 are electrically connected to the plurality of backside conductive layers 230. The external VDD power terminal VDD_ext. 220 is electrically connected to backside conductive paths 244 and vias 246 (resistor R3), which are electrically connected to the first VB 204. The external VSS reference terminal VSS_ext. 222 is electrically connected to backside conductive paths 248 and vias 250 (resistor R3), which are electrically connected to the fourth VB 210. The external IO terminal IOPAD 224 is electrically connected to backside conductive paths 252 and vias 254 (resistor R1), which are electrically connected to the second VB 206. The external IO terminal IOPAD 226 is electrically connected to backside conductive paths 256 and vias 258 (resistor R1), which are electrically connected to the third VB 208.

In some embodiments, a first capacitor C1 260 is situated between the external VDD power terminal VDD_ext. 220 and the external IO terminal IOPAD 224, where one side of the first capacitor C1 260 is at the external VDD power terminal VDD_ext. 220 and another side of the first capacitor C1 260 is at the external IO terminal IOPAD 224. In some embodiments, a second capacitor C2 262 is situated between the external VSS reference terminal VSS_ext. 222 and the external IO terminal IOPAD 226, where one side of the second capacitor C2 262 is at the external VSS reference terminal VSS_ext. 222 and another side of the second capacitor C2 262 is at the external IO terminal IOPAD 226.

Each of the first P-I-N diode 216 and the second P-I-N diode 218 is electrically connected to the plurality of frontside conductive layers 228. The first VB 204 is electrically connected to the N+ region 234 of the first P-I-N diode 216 that is electrically connected to frontside conductive paths 264 and vias 266 (resistor R4) to the internal VDD power terminal VDD_int. 268. The second VB 206 is electrically connected to the P+ region 232 of the first P-I-N diode 216 that is electrically connected to frontside conductive paths 270 and vias 272 (resistor R2′) and to the internal IOPAD terminal PAD_int. 274.

The fourth VB 210 is electrically connected to the P+ region 238 of the second P-I-N diode 218 that is electrically connected to frontside conductive paths 276 and vias 278 (resistor R4) to the internal VSS reference terminal VSS_int. 280. The third VB 208 is electrically connected to the N+ region 240 of the second P-I-N diode 218 that is electrically connected to frontside conductive paths 282 and vias 284 (resistor R2′) and to the internal IOPAD terminal PAD_int. 274.

The internal VDD power terminal VDD_int. 268 is electrically connected to internal circuit victims 286 that are electrically connected to the internal IO terminal PAD_int. 274. Also, the internal VSS reference terminal VSS_int. 280 is electrically connected to internal circuit victims 288 that are electrically connected to the internal IO terminal PAD_int. 274.

In operation, the first P-I-N diode 216 protects the internal circuit victims 286 from ESD by shunting ESD current from the external IO terminals IOPAD 224 and 226 through the second and third VBs 206 and 208, the first P-I-N diode 216, and the first VB 204 to the external VDD power terminal VDD_ext. 220, bypassing the internal circuit victims 286. The second P-I-N diode 218 protects the internal circuit victims 288 from ESD by shunting the ESD current from the external VSS reference terminal VSS_ext. 222 through the fourth VB 210, the second P-I-N diode 218, and the second and third VB 206 and 208 to the external IO terminals IOPAD 224 and 226, bypassing the internal circuit victims 288.

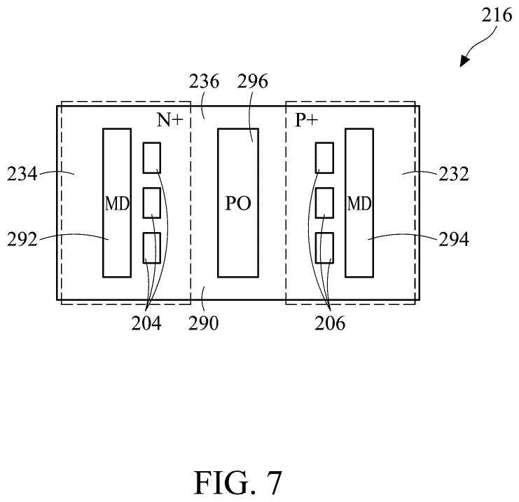

FIG. 7 is a diagram schematically illustrating a top-view of the first P-I-N diode 216, in accordance with some embodiments. The first P-I-N diode 216 includes an active region 290, also referred to as an oxide diffusion region, that includes the P+ region 232, the N+region 234, and the intrinsic region 236. The first VB 204 is formed in the N+ region 234 and the second VB 206 is formed in the P+ region 232. The MD layer 292 is formed on the N+ region 234 and the MD layer 294 is formed on the P+ region 232. The PO layer 296 is formed on the intrinsic region 236.

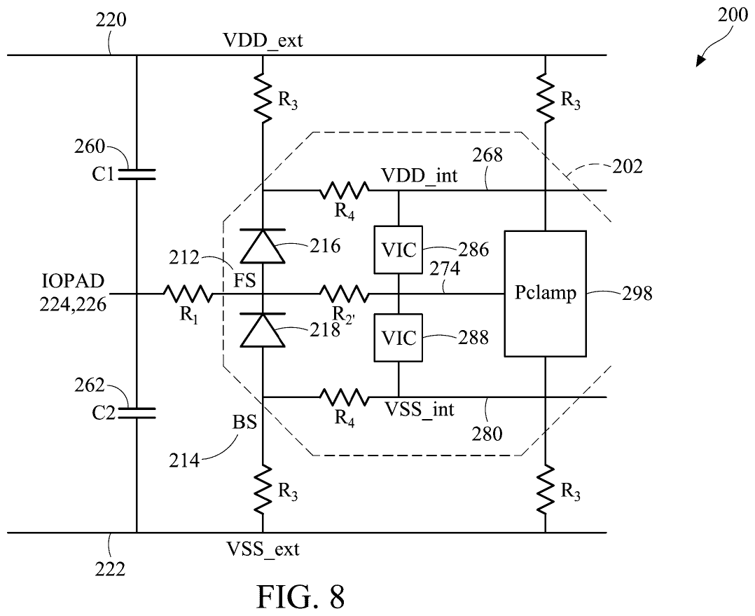

FIG. 8 is a circuit diagram schematically illustrating the device 200 of FIG. 6 with a power-rail clamping circuit 298, in accordance with some embodiments. The device 200 includes the substrate 202 that has the frontside 212 and the backside 214. The device 200 includes the first P-I-N diode 216, the second P-I-N diode 218, the external VDD power terminal VDD_ext. 220, the external VSS reference terminal VSS_ext. 222, and the external IO terminals IOPAD 224 and 226. The first P-I-N diode 216 and the second P-I-N diode 218 are situated on the frontside 212 of the substrate 202. Each of the external VDD power terminal VDD_ext. 220, the external VSS reference terminal VSS_ext. 222, and the external IO terminals IOPAD 224 and 226 is situated under the backside 214 of the substrate 202.

Under the backside 214, the external VDD power terminal VDD_ext. 220 is electrically connected to resistors R3, the external VSS reference terminal VSS_ext. 222 is electrically connected to resistors R3, and the external IO terminals IOPAD 224 and 226 are electrically connected to resistors R1. The first capacitor C1 260 is electrically connected on one side to the external VDD power terminal VDD_ext. 220 and on another side to the external IO terminals IOPAD 224 and 226. The second capacitor C2 262 is electrically connected on one side to the external VSS reference terminal VSS_ext. 222 and on another side to the external IO terminals IOPAD 224 and 226.

The first P-I-N diode 216 is electrically connected through the first VB 204 to the resistor R3 that is electrically connected to the external VDD power terminal VDD_ext. 220. Also, the first P-I-N diode 216 is electrically connected to the resistor R4 that is electrically connected to the internal VDD power terminal VDD_int. 268. The second P-I-N diode 218 is electrically connected through the fourth VB 210 to the resistor R3 that is electrically connected to the external VSS reference terminal VSS_ext. 222. Also, the second P-I-N diode 218 is electrically connected to the resistor R4 that is electrically connected to the internal VSS reference terminal VSS_int. 280.

Each of the first P-I-N diode 216 and the second P-I-N diode 218 is electrically connected to the resistors R2′ that are electrically connected to the internal IO terminal PAD_int. 274. Also, the first P-I-N diode 216 and the second P-I-N diode 218 are electrically connected through the second and third VBs 206 and 208 to the resistors R1 and the external IO terminals IOPAD 224 and 226.

The internal VDD power terminal VDD_int. 268 is electrically connected to internal circuit victims 286 that are electrically connected to the internal IO terminal PAD_int. 274. Also, the internal VSS reference terminal VSS_int. 280 is electrically connected to internal circuit victims 288 that are electrically connected to the internal IO terminal PAD_int. 274.

The power-rail clamping circuit 298 is electrically connected to the internal VDD power terminal VDD_int. 268 and to the internal VSS reference terminal VSS_int. 280. The internal VDD power terminal VDD_int. 268 is electrically connected to the external VDD power terminal VDD_ext. 220 through resistor R3 and, in some embodiments, another VB or an FTV. Also, the internal VSS reference terminal VSS_int. 280 is electrically connected to the external VSS reference terminal VSS_ext. 222 through resistor R3 and, in some embodiments, another VB or an FTV.

In operation, the first P-I-N diode 216 protects the internal circuit victims 286 from ESD by shunting ESD current from the external IO terminals IOPAD 224 and 226 through the second and third VBs 206 and 208, the first P-I-N diode 216, and the first VB 204 to the external VDD power terminal VDD_ext. 220, bypassing the internal circuit victims 286. The second P-I-N diode 218 protects the internal circuit victims 288 from ESD by shunting the ESD current from the external VSS reference terminal VSS_ext. 222 through the fourth VB 210, the second P-I-N diode 218, and the second and third VB 206 and 208 to the external IO terminals IOPAD 224 and 226, bypassing the internal circuit victims 288.

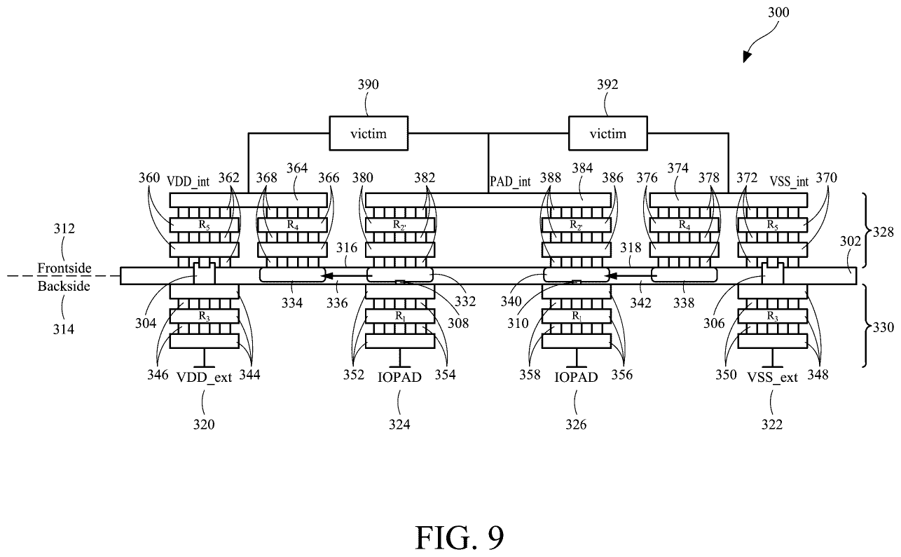

FIG. 9 is a diagram schematically illustrating a device 300 that includes a substrate 302, FTVs 304 and 306, and VBs 308 and 310, in accordance with some embodiments. Each of the FTVs 304 and 306 is a conductive path though the substrate 302, and each of the VBs 308 and 310 is a conductive path through at least part of the substrate 302. In some embodiments, the device 300 is a semiconductor device, an IC device, and/or an electronic device. In some embodiments, the device 300 is part of a wafer. In some embodiments, the device 300 is like the device 20 of FIG. 1.

The device 300 includes the substrate 302 that has a frontside 312 and a backside 314, a first P-I-N diode 316, and a second P-I-N diode 318. Each of the FTVs 304 and 306 extends though the substrate 302 from the frontside 312 to the backside 314. Each of the VBs 308 and 310 extends though the substrate 302 from the backside 314 to one of the first P-I-N diode 316 and the second P-I-N diode 318. In some embodiments, the substrate 302 is a bulk-less process substrate. In some embodiments, the substrate 302 is an SOI substrate. In some embodiments, the substrate 302 is a silicon-insulator-silicon substrate. In some embodiments, the substrate 302 is an SPR process substrate.

The device 300 includes the first P-I-N diode 316, the second P-I-N diode 318, an external VDD power terminal VDD_ext. 320, an external VSS reference terminal VSS_ext. 322, an external IO terminal IOPAD 324, an external IO terminal IOPAD 326, a plurality of frontside conductive layers 328, and a plurality of backside conductive layers 330. The first P-I-N diode 316 and the second P-I-N diode 318 are situated on the frontside 312 of the substrate 302. The first P-I-N diode 316 includes a P+ region 332, an N+ region 334, and an intrinsic region 336. The second P-I-N diode 318 includes a P+region 338, an N+ region 340, and an intrinsic region 342. Each of the external VDD power terminal VDD_ext. 320, the external VSS reference terminal VSS_ext. 322, and the external IO terminals IOPAD 324 and 326 is situated under the backside 314 of the substrate 302.

The external VDD power terminal VDD_ext. 320, the external VSS reference terminal VSS_ext. 322, and the external IO terminals IOPAD 324 and 326 are electrically connected to the plurality of backside conductive layers 330. The external VDD power terminal VDD_ext. 320 is electrically connected to backside conductive paths 344 and vias 346 (resistor R3), which are electrically connected to the first FTV 304. The external VSS reference terminal VSS_ext. 322 is electrically connected to backside conductive paths 348 and vias 350 (resistor R3), which are electrically connected to the second FTV 306. The external IO terminal IOPAD 324 is electrically connected to backside conductive paths 352 and vias 354 (resistor R1), which are electrically connected to the first VB 308. The external IO terminal IOPAD 326 is electrically connected to backside conductive paths 356 and vias 358 (resistor R1), which are electrically connected to the second VB 310.

Each of the first P-I-N diode 316 and the second P-I-N diode 318 is electrically connected to the plurality of frontside conductive layers 328. The first FTV 304 is electrically connected to the N+ region 334 of the first P-I-N diode 316 through frontside conductive paths 360 and vias 362 (resistor R5), the internal VDD power terminal VDD_int. 364, and the frontside conductive paths 366 and vias 368 (resistor R4) to the N+ region 334 of the first P-I-N diode 316. The second FTV 306 is electrically connected to the P+ region 338 of the second P-I-N diode 318 through frontside conductive paths 370 and vias 372 (resistor R5), the internal VSS reference terminal VSS_int. 374, and the frontside conductive paths 376 and vias 378 (resistor R4) to the P+ region 338 of the second P-I-N diode 318.

The first VB 308 is electrically connected to the P+ region 332 of the first P-I-N diode 316 that is electrically connected to frontside conductive paths 380 and vias 382 (resistor R2′) and to the internal IOPAD terminal PAD int. 384. The second VB 310 is electrically connected to the N+ region 340 of the second P-I-N diode 318 that is electrically connected to frontside conductive paths 386 and vias 388 (resistor R2′) and to the internal IOPAD terminal PAD_int. 384.

The internal VDD power terminal VDD_int. 364 is electrically connected to internal circuit victims 390 that are electrically connected to the internal IO terminal PAD_int. 384. Also, the internal VSS reference terminal VSS_int. 374 is electrically connected to internal circuit victims 392 that are electrically connected to the internal IO terminal PAD_int. 384.

In operation, the first P-I-N diode 316 protects the internal circuit victims 390 from ESD by shunting ESD current from the external IO terminals IOPAD 324 and 326 through the first and second VBs 308 and 310, the first P-I-N diode 316, and the first FTV 304 to the external VDD power terminal VDD_ext. 320, bypassing the internal circuit victims 390. The second P-I-N diode 318 protects the internal circuit victims 392 from ESD by shunting the ESD current from the external VSS reference terminal VSS_ext. 322 through the second FTV 306, the second P-I-N diode 318, and the first and second VB 308 and 310 to the external IO terminals IOPAD 324 and 326, bypassing the internal circuit victims 392.

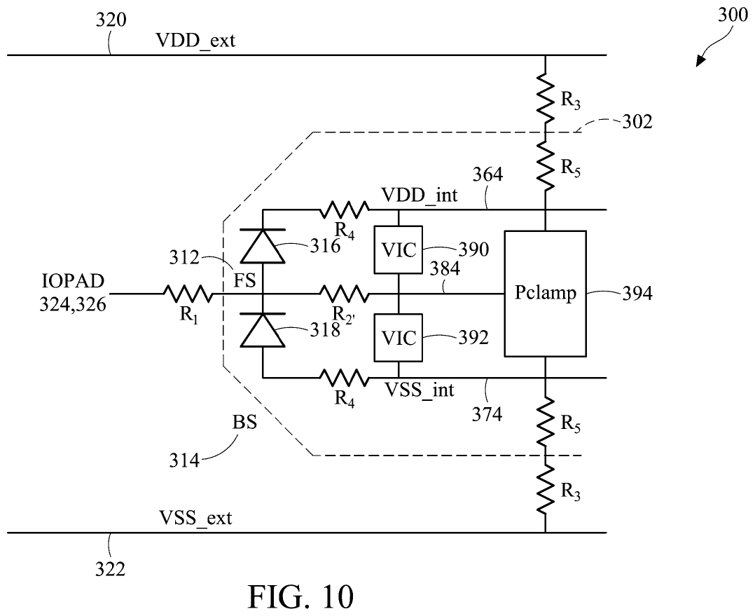

FIG. 10 is a circuit diagram schematically illustrating the device 300 of FIG. 9 with a power-rail clamping circuit 394, in accordance with some embodiments. The device 300 includes the substrate 302 that has the frontside 312 and the backside 314. The device 300 includes the first P-I-N diode 316, the second P-I-N diode 318, the external VDD power terminal VDD_ext. 320, the external VSS reference terminal VSS_ext. 322, and the external IO terminals IOPAD 324 and 326. The first P-I-N diode 316 and the second P-I-N diode 318 are situated on the frontside 312 of the substrate 302. Each of the external VDD power terminal VDD_ext. 320, the external VSS reference terminal VSS_ext. 322, and the external IO terminals IOPAD 324 and 326 is situated under the backside 314 of the substrate 302.

Under the backside 314, the external VDD power terminal VDD_ext. 320 is electrically connected to resistor R3, the external VSS reference terminal VSS_ext. 322 is electrically connected to resistor R3, and the external IO terminals IOPAD 324 and 326 are electrically connected to resistors R1. The distances between the external power/reference terminals and the external IO terminals is larger, such that the device 300 does not have or include capacitors between the external terminals.

The first P-I-N diode 316 is electrically connected to the resistor R4 that is electrically connected to the internal VDD power terminal VDD_int. 364 that is electrically connected to the resistor R5, the first FTV 304, and the resistor R3 to the external VDD power terminal VDD_ext. 320. The second P-I-N diode 318 is electrically connected to the resistor R4 that is electrically connected to the internal VSS reference terminal VSS_int. 374 that is electrically connected to the resistor R5, the second FTV 306, and the resistor R3 to the external VSS reference terminal VSS_ext. 322.

Each of the first P-I-N diode 316 and the second P-I-N diode 318 is electrically connected to the resistors R2′ that are electrically connected to the internal IO terminal PAD_int. 384. Also, the first P-I-N diode 316 and the second P-I-N diode 318 are electrically connected through the first and second VBs 308 and 310 to the resistors R1 and the external IO terminals IOPAD 324 and 326.

The internal VDD power terminal VDD_int. 364 is electrically connected to internal circuit victims 390 that are electrically connected to the internal IO terminal PAD_int. 384. Also, the internal VSS reference terminal VSS_int. 374 is electrically connected to internal circuit victims 392 that are electrically connected to the internal IO terminal PAD_int. 384.

The power-rail clamping circuit 394 is electrically connected to the internal VDD power terminal VDD_int. 364 and to the internal VSS reference terminal VSS_int. 374. The internal VDD power terminal VDD_int. 364 is electrically connected to the external VDD power terminal VDD_ext. 320 through resistor R5 and resistor R3 and, in some embodiments, another VB or FTV. Also, the internal VSS reference terminal VSS_int. 374 is electrically connected to the external VSS reference terminal VSS_ext. 322 through resistor R5 and resistor R3 and, in some embodiments, another VB or FTV.

In operation, the first P-I-N diode 316 protects the internal circuit victims 390 from ESD by shunting ESD current from the external IO terminals IOPAD 324 and 326 through the first and second VBs 308 and 310, the first P-I-N diode 316, and the first FTV 304 to the external VDD power terminal VDD_ext. 320, bypassing the internal circuit victims 390. The second P-I-N diode 318 protects the internal circuit victims 392 from ESD by shunting the ESD current from the external VSS reference terminal VSS_ext. 322 through the second FTV 306, the second P-I-N diode 318, and the first and second VBs 308 and 310 to the external IO terminals IOPAD 324 and 326, bypassing the internal circuit victims 394.

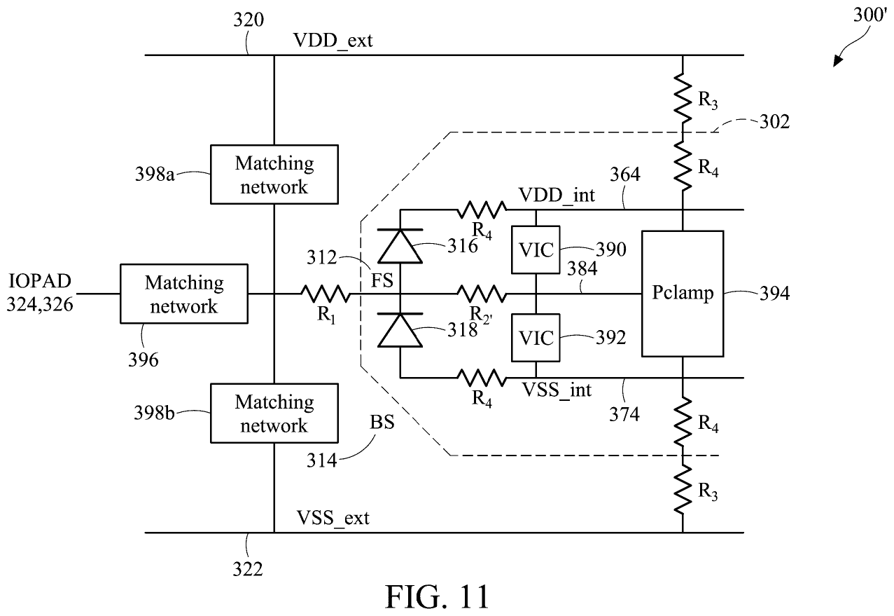

FIG. 11 is a circuit diagram schematically illustrating a device 300′ that includes IO signal channel impedance matching networks 396, 398a, and 398b, in accordance with some embodiments. The device 300′ is like the device 300 of FIG. 10, except for the IO signal channel impedance matching networks 396, 398a, and 398b that are situated on the backside 314 of the device 300′. Each of the impedance matching networks 396, 398a, and 398b includes one or more resistor, capacitor, and/or inductor for matching the impedance of the IO signal channel at the external IO terminals IOPAD 324 and 326. In some embodiments, the impedance matching networks 396, 398a, and 398b are for analog circuits. In some embodiments, the impedance matching networks 396, 398a, and 398b are for radio frequency (RF) circuits.

The device 300′ includes the substrate 302 that has the frontside 312 and the backside 314, the first P-I-N diode 316, the second P-I-N diode 318, the external VDD power terminal VDD_ext. 320, the external VSS reference terminal VSS_ext. 322, and the external IO terminals IOPAD 324 and 326. The first P-I-N diode 316 and the second P-I-N diode 318 are situated on the frontside 312 of the substrate 302. Each of the external VDD power terminal VDD_ext. 320, the external VSS reference terminal VSS_ext. 322, and the external IO terminals IOPAD 324 and 326 is situated under the backside 314 of the substrate 302.

The device 300′ is electrically connected and operates like the device 300 of FIG. 10, except for the impedance matching networks 396, 398a, and 398b. The distances between the external power/reference terminals and the external IO terminals are larger, such that the device 300′ does not have or include capacitors between the external terminals. Instead, the device 300′ includes the impedance matching networks 396, 398a, and 398b. One end of impedance matching network 396 is electrically connected to the external IO terminals IOPAD 324 and 326. The other end of the impedance matching network 396 is electrically connected to one end of the impedance matching network 398a and to one end of the impedance matching network 398b. The other end of the impedance matching network 398a is electrically connected to the external VDD power terminal VDD_ext. 320, and the other end of the impedance matching network 398b is electrically connected to the external VSS reference terminal VSS_ext. 322.

In operation, the impedance matching networks 396, 398a, and 398b match the impedance of the device 300′ at the external IO terminals IOPAD 324 and 326 to the IO signal channel.

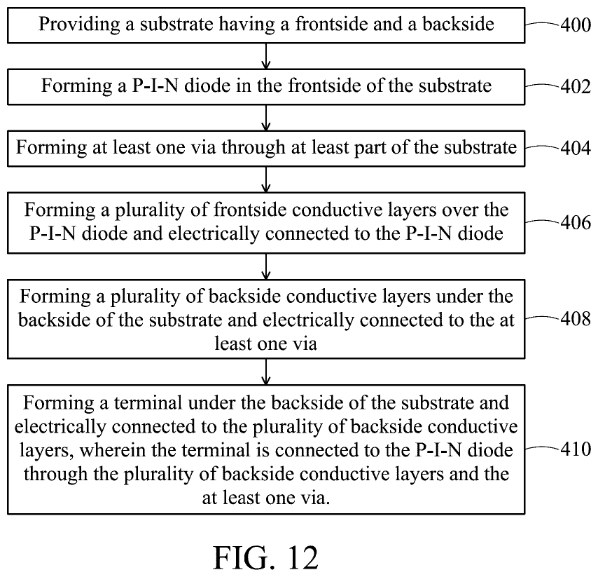

FIG. 12 is a flow-chart diagram schematically illustrating a method of manufacturing an ESD protection circuit, in accordance with some embodiments. At step 400, the method includes providing a substrate having a frontside and a backside. In some embodiments, the substrate is like the substrate 22 of FIG. 1. In some embodiments, the frontside and the backside are like the frontside 24 and the backside 26 of the substrate 22 of FIG. 1.

At step 402, the method includes forming a P-I-N diode, such as the P-I-N diode 28, in the frontside of the substrate. Also, at step 404, the method includes forming at least one via through at least part of the substrate. In some embodiments, the step 402 is performed before the step 404 and, in some embodiments, the step 402 is performed after the step 404. In some embodiments, the steps 402 and 404 are performed at the same time.

At step 406, the method includes forming a plurality of frontside conductive layers, such as the frontside conductive layers 32, over the P-I-N diode and electrically connected to the P-I-N diode, and at step 408, the method includes forming a plurality of backside conductive layers, such as the backside conductive layers 34, under the backside of the substrate and electrically connected to the at least one via. In some embodiments, the step 406 is performed before the step 408 and, in some embodiments, the step 406 is performed after the step 408.

At step 410, the method includes forming a terminal under the backside of the substrate and electrically connected to the plurality of backside conductive layers, wherein the terminal is connected to the P-I-N diode through the plurality of backside conductive layers and the at least one via.

In some embodiments, forming at least one via includes forming an FTV, such as the FTV 104 of FIG. 4, through the substrate from the backside of the substrate to the frontside of the substrate and forming a plurality of frontside conductive layers includes electrically connecting the plurality of frontside conductive layers to the FTV, such that the plurality of backside conductive layers is electrically connected to the plurality of frontside conductive layers through the FTV.

In some embodiments, forming at least one via includes forming a backside via through the substrate from the backside of the substrate to one side of the P-I-N diode, and forming a plurality of backside conductive layers includes electrically connecting the plurality of backside conductive layers to the one side of the P-I-N diode through the backside via. In some embodiments, forming a plurality of frontside conductive layers includes electrically connecting the plurality of frontside conductive layers to the one side of the P-I-N diode, such that the plurality of backside conductive layers are electrically connected to the plurality of frontside conductive layers through the backside via and the one side of the P-I-N diode.

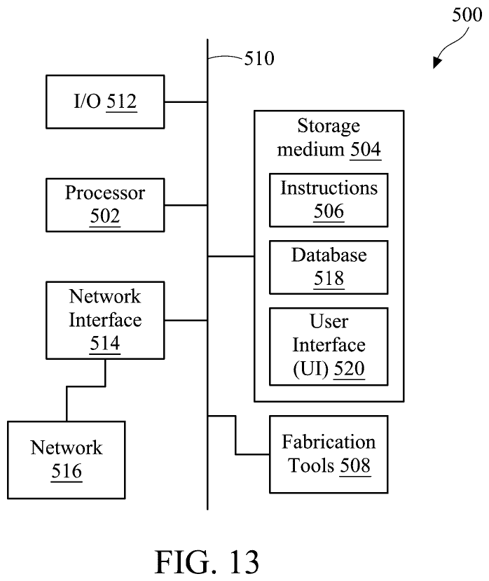

FIG. 13 is a block diagram schematically illustrating an example of a computer system 500 configured to provide the electronic devices, semiconductor devices, and methods of the current disclosure, in accordance with some embodiments. Some or all the design, layout, and manufacture of the semiconductor devices, also referred to as semiconductor circuits, can be performed by or with the aid of the computer system 500. Also, some or all the design, layout, and manufacture of the electronic devices can be performed by or with the aid of the computer system 500. In some embodiments, the computer system 500 includes an electronic design automation (EDA) system. In some embodiments, the semiconductor devices are ICs.

In some embodiments, the system 500 is a general-purpose computing device including a processor 502 and a non-transitory, computer-readable storage medium 504. The computer-readable storage medium 504 may be encoded with, e.g., store, computer program code such as executable instructions 506. Execution of the instructions 506 by the processor 502 provides (at least in part) a design tool that implements a portion or all the functions of the system 500, such as pre-layout simulations, post-layout simulations, routing, rerouting, and final layout for manufacturing. Further, fabrication tools 508 are included to further layout and physically implement the design and manufacture of the semiconductor devices. In some embodiments, execution of the instructions 506 by the processor 502 provides (at least in part) a design tool that implements a portion or all the functions of the system 500. In some embodiments, the system 500 includes a commercial router. In some embodiments, the system 500 includes an automatic place and route (APR) system.

The processor 502 is electrically coupled to the computer-readable storage medium 504 by a bus 510 and to an I/O interface 512 by the bus 510. A network interface 514 is also electrically connected to the processor 502 by the bus 510. The network interface 514 is connected to a network 516, so that the processor 502 and the computer-readable storage medium 504 can connect to external elements using the network 516. The processor 502 is configured to execute the computer program code or instructions 506 encoded in the computer-readable storage medium 504 to cause the system 500 to perform a portion or all the functions of the system 500, such as providing the semiconductor devices and methods of the current disclosure and other functions of the system 500. In some embodiments, the processor 502 is a central processing unit (CPU), a multi-processor, a distributed processing system, an application specific integrated circuit (ASIC), and/or a suitable processing unit.

In some embodiments, the computer-readable storage medium 504 is an electronic, magnetic, optical, electromagnetic, infrared, and/or semiconductor system or apparatus or device. For example, the computer-readable storage medium 504 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 504 can include a compact disk read only memory (CD-ROM), a compact disk read/write memory (CD-R/W), and/or a digital video disc (DVD).

In some embodiments, the computer-readable storage medium 504 stores computer program code or instructions 506 configured to cause the system 500 to perform a portion or all the functions of the system 500. In some embodiments, the computer-readable storage medium 504 also stores information which facilitates performing a portion or all the functions of the system 500. In some embodiments, the computer-readable storage medium 504 stores a database 518 that includes one or more of component libraries, digital circuit cell libraries, and databases.

The system 500 includes the I/O interface 512, which is coupled to external circuitry. In some embodiments, the I/O interface 512 includes a keyboard, keypad, mouse, trackball, trackpad, touchscreen, and/or cursor direction keys for communicating information and commands to the processor 502.

The network interface 514 is coupled to the processor 502 and allows the system 500 to communicate with the network 516, to which one or more other computer systems are connected. The network interface 514 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 500 can be performed in two or more systems that are like system 500.

The system 500 is configured to receive information through the I/O interface 512. The information received through the I/O interface 512 includes one or more of instructions, data, design rules, libraries of components and cells, and/or other parameters for processing by the processor 502. The information is transferred to the processor 502 by the bus 510. Also, the system 500 is configured to receive information related to a user interface (UI) through the I/O interface 512. This UI information can be stored in the computer-readable storage medium 504 as a UI 520.

In some embodiments, a portion or all the functions of the system 500 are implemented via a standalone software application for execution by a processor. In some embodiments, a portion or all the functions of the system 500 are implemented in a software application that is a part of an additional software application. In some embodiments, a portion or all the functions of the system 500 are implemented as a plug-in to a software application. In some embodiments, at least one of the functions of the system 500 is implemented as a software application that is a portion of an EDA tool. In some embodiments, a portion or all the functions of the system 500 are implemented as a software application that is used by the system 500. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 500 include fabrication tools 508 for implementing the manufacturing processes of the system 500. For example, based on the final layout, photolithographic masks may be generated, which are used to fabricate the semiconductor device by the fabrication tools 508.

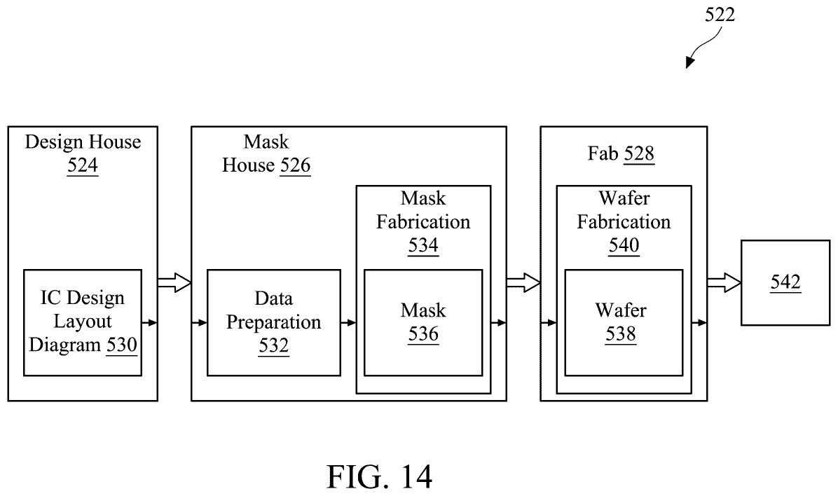

Further aspects of device fabrication are disclosed in conjunction with FIG. 14, which is a block diagram of a semiconductor device manufacturing system 522 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 522.

In FIG. 14, the semiconductor device manufacturing system 522 includes entities, such as a design house 524, a mask house 526, and a semiconductor device manufacturer/fabricator (“Fab”) 528, that interact with one another in the design, development, and manufacturing cycles and/or services related to manufacturing a semiconductor device, such as the semiconductor devices described herein. The entities in the system 522 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 524, the mask house 526, and the semiconductor device fab 528 are owned by a single larger company. In some embodiments, two or more of the design house 524, the mask house 526, and the semiconductor device fab 528 coexist in a common facility and use common resources.

The design house (or design team) 524 generates a semiconductor device design layout diagram 530. The semiconductor device design layout diagram 530 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 530 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 524 implements a design procedure to form a semiconductor device design layout diagram 530. The semiconductor device design layout diagram 530 is presented in one or more data files having information of the geometrical patterns. For example, semiconductor device design layout diagram 530 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 526 includes data preparation 532 and mask fabrication 534. The mask house 526 uses the semiconductor device design layout diagram 530 to manufacture one or more masks 536 to be used for fabricating the various layers of the semiconductor device or semiconductor structure. The mask house 526 performs mask data preparation 532, where the semiconductor device design layout diagram 530 is translated into a representative data file (RDF). The mask data preparation 532 provides the RDF to the mask fabrication 534. The mask fabrication 534 includes a mask writer that converts the RDF to an image on a substrate, such as a mask (reticle) 536 or a semiconductor wafer 538. The design layout diagram 530 is manipulated by the mask data preparation 532 to comply with characteristics of the mask writer and/or criteria of the semiconductor device fab 528. In FIG. 14, the mask data preparation 532 and the mask fabrication 534 are illustrated as separate elements. In some embodiments, the mask data preparation 532 and the mask fabrication 534 can be collectively referred to as mask data preparation.

In some embodiments, the mask data preparation 532 includes an optical proximity correction (OPC) which uses lithography enhancement techniques to compensate for image errors, such as those that can arise from diffraction, interference, other process effects and the like. The OPC adjusts the semiconductor device design layout diagram 530. In some embodiments, the mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 532 includes a mask rule checker (MRC) that checks the semiconductor device design layout diagram 530 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 530 to compensate for limitations during the mask fabrication 534, which may undo part of the modifications performed by OPC to meet mask creation rules.

In some embodiments, the mask data preparation 532 includes lithography process checking (LPC) that simulates processing that will be implemented by the semiconductor device fab 528. LPC simulates this processing based on the semiconductor device design layout diagram 530 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 530.

The above description of mask data preparation 532 has been simplified for the purposes of clarity. In some embodiments, data preparation 532 includes additional features such as a logic operation (LOP) to modify the semiconductor device design layout diagram 530 according to manufacturing rules. Additionally, the processes applied to the semiconductor device design layout diagram 530 during data preparation 532 may be executed in a variety of different orders.

After the mask data preparation 532 and during the mask fabrication 534, a mask 536 or a group of masks 536 are fabricated based on the modified semiconductor device design layout diagram 530. In some embodiments, the mask fabrication 534 includes performing one or more lithographic exposures based on the semiconductor device design layout diagram 530. In some embodiments, an electron-beam (e-beam) or a mechanism of multiple e-beams is used to form a pattern on a mask (photomask or reticle) 536 based on the modified semiconductor device design layout diagram 530. The mask 536 can be formed in various technologies. In some embodiments, the mask 536 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 536 includes a transparent substrate (e.g., fused quartz) and an opaque material (e.g., chromium) coated in the opaque regions of the binary mask. In another example, the mask 536 is formed using a phase shift technology. In a phase shift mask (PSM) version of the mask 536, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 534 is used in a variety of processes. For example, such a mask(s) is used in an ion implantation process to form various doped regions in the semiconductor wafer 538, in an etching process to form various etching regions in the semiconductor wafer 538, and/or in other suitable processes.

The semiconductor device fab 528 includes wafer fabrication 540. The semiconductor device fab 528 is a semiconductor device fabrication business that includes one or more manufacturing facilities for the fabrication of a variety of different semiconductor device products. In some embodiments, the semiconductor device fab 528 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 528 uses the mask(s) 536 fabricated by the mask house 526 to fabricate the semiconductor structures or semiconductor devices 542 of the current disclosure. Thus, the semiconductor device fab 528 at least indirectly uses the semiconductor device design layout diagram 530 to fabricate the semiconductor structures or semiconductor devices 542 of the current disclosure. Also, the semiconductor wafer 538 includes a silicon substrate or other proper substrate having material layers formed thereon, and the semiconductor wafer 538 further includes one or more of various doped regions, dielectric features, multilevel interconnects, and the like (formed at subsequent manufacturing steps). In some embodiments, the semiconductor wafer 538 is fabricated by the semiconductor device fab 528 using the mask(s) 536 to form the semiconductor structures or semiconductor devices 542 of the current disclosure. In some embodiments, the semiconductor device fabrication includes performing one or more lithographic exposures based at least indirectly on the semiconductor device design layout diagram 530.

Disclosed embodiments thus provide ESD protection circuits and schemes that include a device that includes a substrate having a frontside and a backside with a P-I-N diode situated on the frontside of the substrate and a terminal situated under the backside of the substrate. A plurality of frontside conductive layers are situated over the P-I-N diode and electrically connected to the P-I-N diode, and a plurality of backside conductive layers are situated under the backside of the substrate and electrically connected to the terminal. The terminal is electrically connected to the P-I-N diode through the plurality of backside conductive layers and at least one via, such as an FTV or a VB.

In some embodiments, the at least one via includes an FTV that extends through the substrate from the backside of the substrate to the frontside of the substrate, where the plurality of backside conductive layers are electrically connected to the plurality of frontside conductive layers by the FTV. In some embodiments, the at least one via includes a VB that extends through the substrate from the backside of the substrate to one side of the P-I-N diode, where the plurality of backside conductive layers are electrically connected to the one side of the P-I-N diode by the VB. In some embodiments, the plurality of backside conductive layers are electrically connected to the plurality of frontside conductive layers through the VB and the one side of the P-I-N diode.

In some embodiments, the devices do not have or include capacitors between the power/reference terminals and the IO terminals, such as between a VDD power terminal and an IO terminal and/or between an IO terminal and a VSS reference terminal. Also, in some embodiments, the devices include impedance matching networks for matching the impedance of the device to the IO signal channel, where the impedance matching networks include one or more capacitors, inductors, and/or resistors.

In accordance with some embodiments, a device including a substrate having a frontside and a backside, a first P-I-N diode situated on the frontside of the substrate, a first terminal situated under the backside of the substrate, a plurality of frontside conductive layers, and a plurality of backside conductive layers. The plurality of frontside conductive layers situated over the first P-I-N diode and electrically connected to the first P-I-N diode. The plurality of backside conductive layers situated under the backside of the substrate and electrically connected to the first terminal that is electrically connected to the first P-I-N diode through the plurality of backside conductive layers and at least one via.

In accordance with further embodiments, a device includes a substrate having a frontside and a backside, a first P-I-N diode situated on the frontside of the substrate, a first terminal situated under the backside of the substrate, a second terminal situated under the backside of the substrate, a first frontside conductive path, a second frontside conductive path, a first backside conductive path, and a second backside conductive path. The first frontside conductive path is situated over a first side of the first P-I-N diode and electrically connected to the first side of the first P-I-N diode. The second frontside conductive path is situated over a second side of the first P-I-N diode and electrically connected to the second side of the first P-I-N diode. The first backside conductive path is situated under the backside of the substrate and electrically connected to the first terminal, and the second backside conductive path is situated under the backside of the substrate and electrically connected to the second terminal. The device further includes an FTV that extends through the substrate from the backside of the substrate to the frontside of the substrate, wherein the first backside conductive path is electrically connected to the first frontside conductive path through the FTV, and a first VB that extends through the substrate from the backside of the substrate to the second side of the first P-I-N diode, wherein the second backside conductive path is electrically connected to the second side of the first P-I-N diode through the first VB.

In accordance with still further disclosed aspects, a method of manufacturing an ESD protection circuit. The method includes providing a substrate having a frontside and a backside, forming a P-I-N diode in the frontside of the substrate, forming at least one via through at least part of the substrate, forming a plurality of frontside conductive layers over the P-I-N diode and electrically connected to the P-I-N diode, forming a plurality of backside conductive layers under the backside of the substrate and electrically connected to the at least one via, and forming a terminal under the backside of the substrate and electrically connected to the plurality of backside conductive layers, wherein the terminal is connected to the P-I-N diode through the plurality of backside conductive layers and the at least one via.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes. substitutions, and alterations herein without departing from the spirit and scope of the present disclosure.

What is claimed is:

1. A device, comprising:
a substrate having a frontside and a backside;
a first P-I-N diode situated on the frontside of the substrate;
a first terminal situated under the backside of the substrate;
a plurality of frontside conductive layers situated over the first P-I-N diode and electrically connected to the first P-I-N diode; and
a plurality of backside conductive layers situated under the backside of the substrate and electrically connected to the first terminal,
wherein the first terminal is electrically connected to the first P-I-N diode through the plurality of backside conductive layers and at least one via in the substrate.

2. The device of claim 1, comprising a feed-through-via that extends through the substrate from the backside of the substrate to the frontside of the substrate, wherein the plurality of backside conductive layers are electrically connected to the plurality of frontside conductive layers by the feed-through-via.

3. The device of claim 1, comprising a backside via that extends through the substrate from the backside of the substrate to one side of the first P-I-N diode, wherein the plurality of backside conductive layers are electrically connected to the one side of the first P-I-N diode by the backside via.

4. The device of claim 3, wherein the plurality of frontside conductive layers are electrically connected to the one side of the first P-I-N diode, such that the plurality of backside conductive layers are electrically connected to the plurality of frontside conductive layers through the backside via and the one side of the first P-I-N diode.

5. The device of claim 1, wherein the first terminal is one of a power terminal, a reference terminal, and an input/output (IO) terminal.

6. The device of claim 1, comprising a power-rail clamping circuit electrically connected to the plurality of frontside conductive layers.

7. The device of claim 1, comprising a second P-I-N diode situated on the frontside of the substrate and a second terminal situated under the backside of the substrate, wherein the plurality of frontside conductive layers are electrically connected to the second P-I-N diode and the plurality of backside conductive layers are electrically connected to the second terminal.

8. The device of claim 7, wherein the second terminal is electrically connected to the second P-I-N diode through the plurality of backside conductive layers that are electrically connected to the plurality of frontside conductive layers.

9. The device of claim 7, comprising a capacitor having one end connected to the first terminal and another end connected to the second terminal.

10. The device of claim 1, comprising a feed-through-via that extends through the substrate from the backside of the substrate to the frontside of the substrate, wherein the plurality of backside conductive layers are electrically connected to the plurality of frontside conductive layers by the feed-through-via, and comprising a backside via that extends through the substrate from the backside of the substrate to one side of the first P-I-N diode, wherein the plurality of backside conductive layers are electrically connected to the one side of the first P-I-N diode by the backside via.

11. A device, comprising:
a substrate having a frontside and a backside;
a first P-I-N diode situated on the frontside of the substrate;
a first terminal situated under the backside of the substrate;
a second terminal situated under the backside of the substrate;
a first frontside conductive path situated over a first side of the first P-I-N diode and electrically connected to the first side of the first P-I-N diode;
a second frontside conductive path situated over a second side of the first P-I-N diode and electrically connected to the second side of the first P-I-N diode;
a first backside conductive path situated under the backside of the substrate and electrically connected to the first terminal;
a second backside conductive path situated under the backside of the substrate and electrically connected to the second terminal;
a feed-through-via that extends through the substrate from the backside of the substrate to the frontside of the substrate, wherein the first backside conductive path is electrically connected to the first frontside conductive path through the feed-through-via; and
a first backside via that extends through the substrate from the backside of the substrate to the second side of the first P-I-N diode, wherein the second backside conductive path is electrically connected to the second side of the first P-I-N diode through the first backside via.

12. The device of claim 11, wherein the second backside conductive path is electrically connected to the second frontside conductive path through the first backside via and the second side of the first P-I-N diode.

13. The device of claim 11, wherein the first terminal is one of a power terminal or a reference terminal, and the second terminal is an input/output (IO) terminal.

14. The device of claim 11, comprising a power-rail clamping circuit electrically connected to frontside conductive layers.

15. The device of claim 11, a second P-I-N diode situated on the frontside of the substrate, wherein the second frontside conductive path is electrically connected to a first side of the second P-I-N diode, and a third backside conductive path is electrically connected to the second terminal or a third terminal situated under the backside of the substrate.

16. The device of claim 15, wherein the second terminal or the third terminal is electrically connected to the first side of the second P-I-N diode through the third backside conductive path that is electrically connected to the second frontside conductive path through a second backside via and the first side of the second P-I-N diode.

17. A method of manufacturing an electrostatic discharge (ESD) protection circuit, the method comprising:
providing a substrate having a frontside and a backside;
forming a P-I-N diode in the frontside of the substrate;
forming at least one via through at least part of the substrate;
forming a plurality of frontside conductive layers over the P-I-N diode and electrically connected to the P-I-N diode;
forming a plurality of backside conductive layers under the backside of the substrate and electrically connected to the at least one via; and
forming a terminal under the backside of the substrate and electrically connected to the plurality of backside conductive layers, wherein the terminal is connected to the P-I-N diode through the plurality of backside conductive layers and the at least one via.

18. The method of claim 17, wherein forming at least one via includes forming a feed-through-via through the substrate from the backside of the substrate to the frontside of the substrate and forming a plurality of frontside conductive layers includes electrically connecting the plurality of frontside conductive layers to the feed-through-via, such that the plurality of backside conductive layers is electrically connected to the plurality of frontside conductive layers through the feed-through-via.

19. The method of claim 17, wherein forming at least one via includes forming a backside via through the substrate from the backside of the substrate to one side of the P-I-N diode, and forming a plurality of backside conductive layers includes electrically connecting the plurality of backside conductive layers to the one side of the P-I-N diode through the backside via.

20. The method of claim 19, wherein forming a plurality of frontside conductive layers includes electrically connecting the plurality of frontside conductive layers to the one side of the P-I-N diode, such that the plurality of backside conductive layers are electrically connected to the plurality of frontside conductive layers through the backside via and the one side of the P-I-N diode.
